(19) United States
(12) Patent Application Publication
(10) Pub. No.: US 2026/0282240 A1
(43) Pub. Date: Sep. 17, 2026

(54) METHOD FOR MANUFACTURING ELECTRONIC COMPONENT BUILT-IN SUBSTRATE AND ELECTRONIC COMPONENT BUILT-IN SUBSTRATE

(71) Applicant: IBIDEN CO., LTD., Gifu (JP)

(72) Inventor: Kazuki KAJIHARA, Gifu (JP)

(73) Assignee: IBIDEN CO., LTD., Gifu (JP)

(21) Appl. No.: 19/308,668

(22) Filed: Aug. 25, 2025

(30) Foreign Application Priority Data
Aug. 26, 2024 (JP) 2024-144111

(51) Int. Cl. H05K 3/30; H05K 1/183; H05K 1/185; H05K 3/00

(52) U.S. Cl. CPC H05K 3/30; H05K 1/183; H05K 1/185; H05K 3/0044

(57) ABSTRACT

An electronic component built-in substrate includes a core substrate having a cavity, an electronic component assembly accommodated in the cavity and including electronic components, and a resin filler filling the cavity of the core substrate such that the resin filler is covering the core substrate and the electronic component assembly. The electronic component assembly includes a mold resin covering the entirety of the electronic components and having a sloped surface such that the sloped surface of the mold resin is inclined from the top of the electronic component assembly to the bottom of the electronic component assembly.

### CROSS-REFERENCE TO RELATED APPLICATIONS

The present application is based upon and claims the benefit of priority to Japanese Patent Application No. 2024-144111, filed Aug. 26, 2024, the entire contents of which are incorporated herein by reference.

### BACKGROUND OF THE INVENTION

### Field of the Invention

The present invention relates to a method for manufacturing an electronic component built-in substrate and the electronic component built-in substrate. More specifically, the present invention relates to a method for manufacturing an electronic component built-in substrate with multiple electronic components built-in and the electronic component built-in substrate.

### Description of Background Art

Japanese Patent Application Laid-Open Publication No. 2015-220283 describes a printed wiring board with electronic components in an opening. The entire contents of this publication are incorporated herein by reference.

### SUMMARY OF THE INVENTION

According to one aspect of the present invention, a method for manufacturing an electronic component built-in substrate includes preparing a core substrate, forming a cavity in the core substrate such that the cavity is formed to accommodate an electronic component assembly, placing an adhesive tape on a surface of the core substrate such that the adhesive tape covers the cavity formed in the core substrate, temporarily fixing the electronic component assembly on a portion of the adhesive tape exposed in the cavity formed in the core substrate, filling the cavity in which the electronic component assembly is temporarily fixed with a resin filler such that the resin filler covers the electronic component assembly, curing the resin filler filling the cavity in which the electronic component assembly is temporarily fixed, and removing the adhesive tape from the surface of the core substrate such that an electronic component built-in substrate having the electronic component assembly incorporated inside the cavity of the core substrate via the resin filler is formed. The electronic component assembly includes electronic components and a mold resin covering the entirety of the electronic components and having a sloped surface such that the sloped surface of the mold resin is inclined from the top of the electronic component assembly to the bottom of the electronic component assembly.

According to another aspect of the present invention, an electronic component built-in substrate includes a core substrate having a cavity, an electronic component assembly accommodated in the cavity and including electronic components, and a resin filler filling the cavity of the core substrate such that the resin filler is covering the core substrate and the electronic component assembly. The electronic component assembly includes a mold resin covering the entirety of the electronic components and having a sloped surface such that the sloped surface of the mold resin is inclined from the top of the electronic component assembly to the bottom of the electronic component assembly.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a top view describing an electronic component built-in substrate according to an embodiment of the present invention;

FIG. 1B is a cross-sectional view describing the electronic component built-in substrate according to the embodiment of the present invention;

FIG. 2A is a cross-sectional view describing a method for manufacturing an electronic component built-in substrate according to an embodiment of the present invention;

FIG. 2B is a cross-sectional view describing a method for manufacturing an electronic component built-in substrate according to an embodiment of the present invention;

FIG. 2C is a cross-sectional view describing a method for manufacturing an electronic component built-in substrate according to an embodiment of the present invention;

FIG. 2D is a cross-sectional view describing a method for manufacturing an electronic component built-in substrate according to an embodiment of the present invention;

FIG. 2E is a cross-sectional view describing a method for manufacturing an electronic component built-in substrate according to an embodiment of the present invention;

FIG. 2F is a cross-sectional view a method for manufacturing an electronic component built-in substrate according to an embodiment of the present invention;

FIG. 2G(a) and 2G(b) are cross-sectional views describing a method for manufacturing an electronic component built-in substrate according to an embodiment of the present invention;

FIG. 2H(a) and 2H(b) are cross-sectional views describing a method for manufacturing an electronic component built-in substrate according to an embodiment of the present invention;

FIG. 2I is a cross-sectional view describing a method for manufacturing an electronic component built-in substrate according to an embodiment of the present invention;

FIG. 2J is a cross-sectional view describing a method for manufacturing an electronic component built-in substrate according to an embodiment of the present invention;

FIG. 2K is a cross-sectional view describing a method for manufacturing an electronic component built-in substrate according to an embodiment of the present invention; and

FIG. 3 is a plan view of a cavity in a core substrate of a conventional printed wiring board.

### DETAILED DESCRIPTION OF THE EMBODIMENTS

Embodiments will now be described with reference to the accompanying drawings, wherein like reference numerals designate corresponding or identical elements throughout the various drawings.

### Electronic Component Built-In Substrate

A method for manufacturing an electronic component built-in substrate and an electronic component built-in substrate according to embodiments of the present invention are described with reference to the drawings.

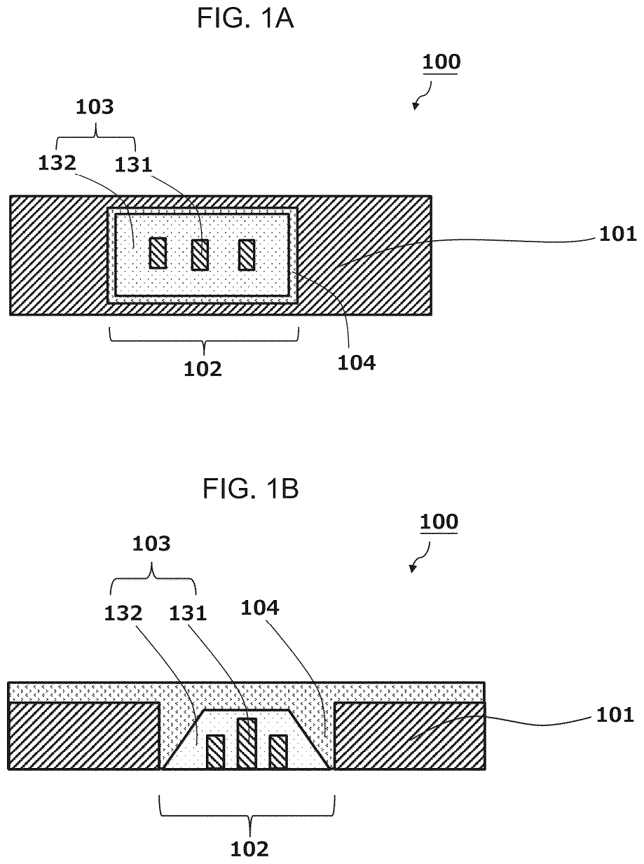

FIG. 1A is a top view for describing an electronic component built-in substrate according to an embodiment of the present invention. As illustrated in FIG. 1A, the electronic component built-in substrate 100 includes a core substrate 101, a cavity 102 formed inside the core substrate 101, an electronic component assembly 103 accommodated in the cavity 102, and a resin filler 104 that covers the core substrate 101 and the electronic component assembly 103.

The core substrate 101 may be a copper-clad laminate having a seed layer made of copper foil formed on both sides of a substrate. As the copper-clad laminate, a commercially available one can be used. Further, the core substrate 101 may be a multilayer core substrate in which multiple resin insulating layers and multiple conductor layers are alternately laminated.

The cavity 102 is formed inside the core substrate 101 to accommodate the electronic component assembly 103. The electronic component assembly 103 is composed of multiple electronic components 131 and a mold resin 132. The cavity 102 is not particularly limited in shape as long as it is capable of accommodating the electronic component assembly 103. The cavity 102 may have a simple shape, for example, a rectangular shape in a plan view. That is, the cavity 102 can adopt a simplified shape from a point of view of a manufacturing process of the electronic component built-in substrate 100.

In other words, the cavity 102 does not require providing a protrusion to separate one electronic component from another electronic component, even when accommodating multiple electronic components. Further, the cavity 102 does not require providing a communication part that connects a space for accommodating one electronic component with a space for accommodating another electronic component. In this way, even when multiple electronic components are incorporated inside the cavity 102 formed in the core substrate 101, the electronic component built-in substrate 100 can accommodate these electronic components without complicating the shape of the cavity 102.

FIG. 1B is a cross-sectional view for describing an electronic component built-in substrate manufactured using a method for manufacturing an electronic component built-in substrate according to an embodiment of the present invention. As illustrated in FIG. 1B, the electronic component assembly 103 is composed of the multiple electronic components 131 and the mold resin 132 that covers the entirety of the multiple electronic components 131. Here, the electronic components 131 constituting the electronic component assembly 103 may be electronic components such as multilayer ceramic chip capacitors, chip resistors, inductors, or thermistors.

The number of the electronic components 131 can be appropriately set according to performance of the electronic component built-in substrate 100 to be manufactured and may be 2 to 10. Thus, by adopting the electronic component assembly 103, the electronic component built-in substrate 100 can incorporate the multiple electronic components 131 inside the cavity 102 formed in the core substrate 101.

Here, the multiple electronic components 131 may have the same thickness (height) or different thicknesses (heights). The multiple electronic components 131 may have the same length or different lengths. Further, the multiple electronic components 131 may have the same width or different widths.

That is, the electronic component built-in substrate 100 adopts the electronic component assembly 103 containing the multiple electronic components 131, rather than handling each electronic component 131 separately and independently, to incorporate the multiple electronic components 131 into the core substrate 101. Therefore, the electronic component built-in substrate 100 can incorporate multiple electronic components 131 of different sizes inside the cavity 102 of the electronic component built-in substrate 100 with high positioning accuracy, without being subjected to structural restrictions such as sizes or forms derived from the forms of the individual electronic components 131.

The mold resin 132 constituting the electronic component assembly 103 may contain a thermosetting epoxy resin and may be formed from a resin composition mixed with fine silica (SiO₂, silicon dioxide) particles. The mold resin 132 can be formed by heating and softening a pellet-shaped resin composition in a plunger, pressing the molten resin composition into a mold, and cooling and solidifying it.

Here, the mold resin 132 has a sloped surface that is inclined from top to bottom. That is, the mold resin 132 is formed inside the cavity 102 such that its wall surface is inclined from top to bottom. By having a sloped surface that is inclined from top to bottom, the mold resin 132 enables the molten resin filler 104 to be sufficiently filled into a gap between a sidewall of the cavity 102 and the electronic component assembly 103, even when the gap is small.

The electronic component built-in substrate 100 includes the resin filler 104 that covers the core substrate 101 and the electronic component assembly 103. That is, the electronic component built-in substrate 100 includes the resin filler 104 for filling an entire surface of the core substrate 101 and a gap formed between the core substrate 101 and the electronic component assembly 103. The resin filler 104 may be a resin composition containing an inorganic filler such as silica or alumina and an epoxy resin, and specifically, may be an electrically insulating material in which a glass cloth is impregnated with a thermosetting resin such as an epoxy resin or a bismaleimide triazine resin.

The electronic component built-in substrate 100 having such a structure is used as a core substrate constituting a multilayer printed wiring board, and a build-up layer (not illustrated) can be formed on an upper surface of the core substrate. As described above, in the electronic component built-in substrate 100, even when the gap formed between the sidewall of the cavity 102 and the electronic component assembly 103 is small, the molten resin filler 104 is sufficiently filled into the gap. Therefore, a printed wiring board provided with the electronic component built-in substrate 100, in which multiple electronic components are positioned with high precision, can be reduced in size.

### Method for Manufacturing Electronic Component Built-In Substrate

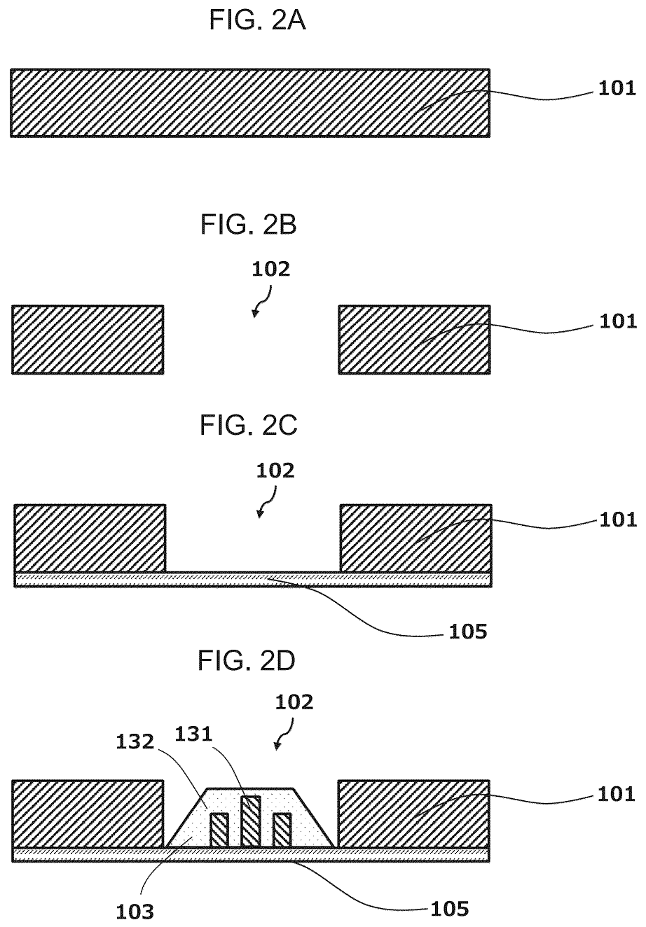

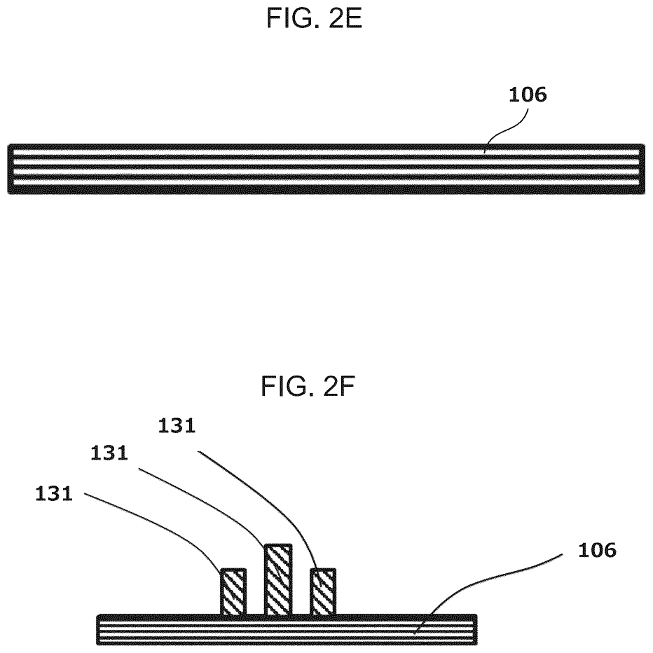

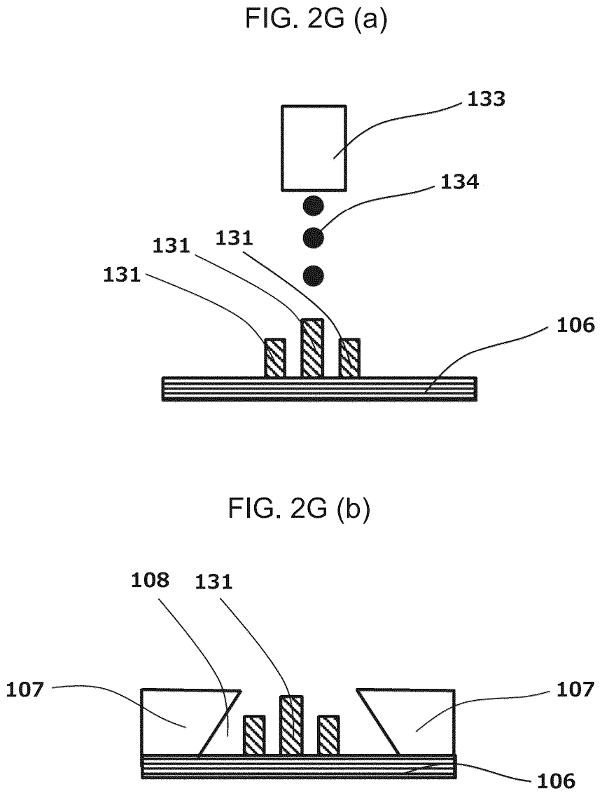

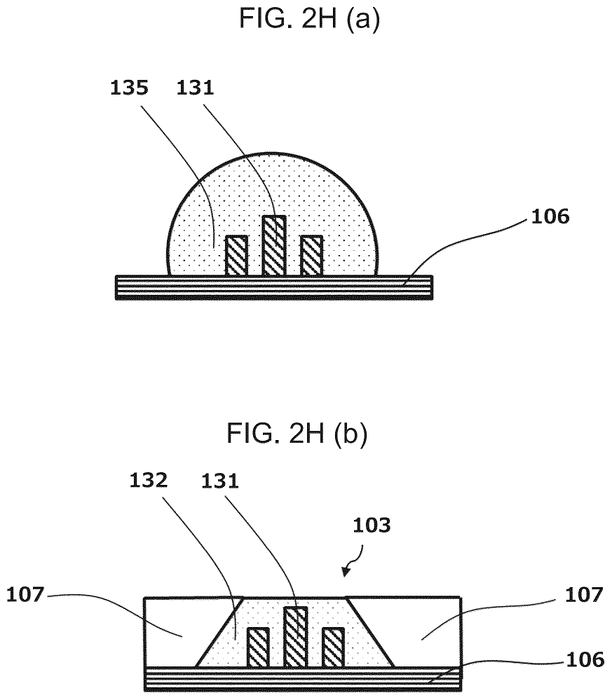

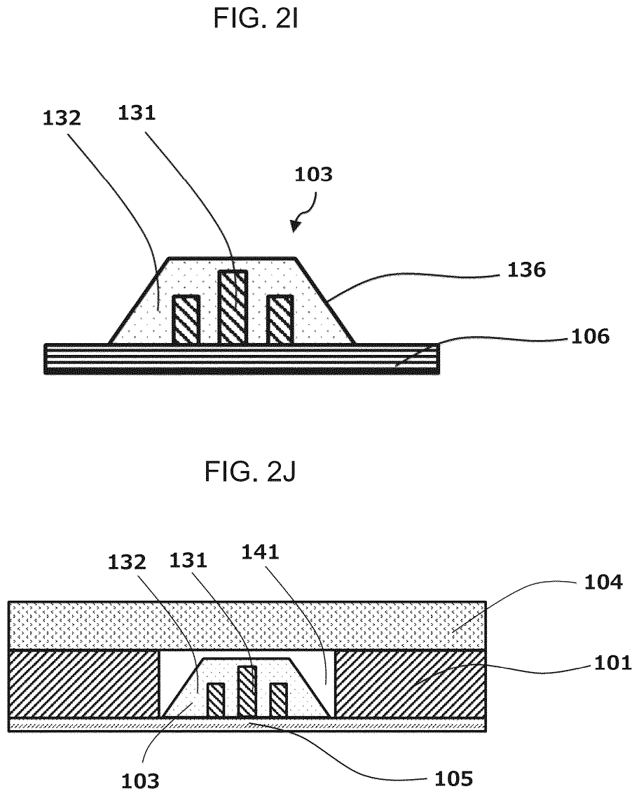

FIGS. 2A to 2K describe a method for manufacturing an electronic component built-in substrate according to an embodiment of the present invention.

First, as illustrated in FIG. 2A, the core substrate 101 is prepared. The core substrate 101 may be, for example, a copper-clad laminate in which seed layers made of copper foil are respectively formed on both surfaces of a substrate, and as the copper-clad laminate, a commercially available one may be prepared.

Next, as illustrated in FIG. 2B, the cavity 102 for accommodating the electronic component assembly 103 is formed in the core substrate 101. Forming the cavity 102 can be performed by predetermining a location where the cavity 102 is to be formed, and then easily processing the core substrate 101 with laser or the like so as to penetrate it.

Forming the cavity 102 does not require providing a protrusion to separate one electronic component from another electronic component. Further, the cavity 102 does not require providing a communication part that connects a space for accommodating one electronic component with a space for accommodating another electronic component.

Therefore, a method for manufacturing an electronic component built-in substrate according to an embodiment of the present invention easily forms the cavity 102 for accommodating the electronic component assembly 103 in the core substrate 101.

Next, as illustrated in FIG. 2C, an adhesive tape 105 is placed on a lower surface of the core substrate 101. The adhesive tape 105 is placed such that an upper surface, which is an adhesive surface, of the adhesive tape 105, is in contact with the lower surface of the core substrate 101.

Next, as illustrated in FIG. 2D, the electronic component assembly 103 is temporarily fixed onto the adhesive tape 105 exposed inside the cavity 102. Temporarily fixing the electronic component assembly 103 is performed such that the electronic component assembly 103 is accommodated inside the cavity 102. A width of a lower surface of the electronic component assembly 103 is designed to be slightly smaller than a width of a lower surface of the cavity 102. Therefore, temporarily fixing the electronic component assembly 103 onto the adhesive tape 105 exposed inside the cavity 102 can be extremely easily performed.

The electronic component assembly 103 is composed of the multiple electronic components 131 and the mold resin 132 that covers the entirety of the multiple electronic components 131. The multiple electronic components 131 are already precisely positioned within the electronic component assembly 103 by being fixed by the mold resin 132.

Therefore, a method for manufacturing an electronic component built-in substrate according to an embodiment of the present invention allows multiple electronic components 131 to be extremely easily incorporated in a state of being positioned with high precision inside the one cavity 102 having a simple shape, without the individual electronic components 131 included in the multiple electronic components 131 interfering with each other.

Moreover, a method for manufacturing an electronic component built-in substrate according to an embodiment of the present invention does not involve directly placing each electronic component 131 constituting the multiple electronic components 131 inside the cavity 102. Therefore, a method for manufacturing an electronic component built-in substrate according to an embodiment of the present invention allows the electronic components 131 to be extremely easily incorporated in a state of being positioned with high precision inside the cavity 102, even when there is a significant difference in thickness between the core substrate 101 having the cavity 102 and the electronic components 131.

Here, the electronic component assembly 103 may be manufactured, for example, by adopting the following manufacturing process (I). Specifically, as illustrated in FIG. 2E, a carrier 106 is prepared for forming the electronic component assembly 103 composed of the multiple electronic components 131 and the mold resin 132. The carrier 106 preferably has a shape that has a lower surface slightly larger than the lower surface of the electronic component assembly 103. A thickness of the carrier 106 is preferably 1 to 20 μm, and particularly preferably less than 10 μm. A material constituting the carrier 106 is preferably a polyester-based material, such as polyethylene terephthalate (PET) or polybutylene terephthalate (PBT).

Next, as illustrated in FIG. 2F, the multiple electronic components 131 are placed on an upper surface of the carrier 106. The multiple electronic components 131 may have the same thickness (height) or different thicknesses (heights). Further, the multiple electronic components 131 may have the same length or different lengths. Moreover, the multiple electronic components 131 may have the same width or different widths. An order in which the multiple different electronic components 131 are positioned can be appropriately set. A spacing formed between adjacent electronic components 131 can be appropriately set.

Next, as illustrated in FIG. 2G(a), a molten mold resin 134 is poured from a plunger 133 from above the multiple electronic components 131 so as to cover the multiple electronic components 131. Further, as illustrated in FIG. 2H(a), the molten mold resin 134 poured so as to cover the multiple electronic components 131 is cooled and solidified. By solidifying the molten mold resin 134, the molten mold resin 134 becomes a solidified mold resin 135.

Next, as illustrated in FIG. 2I, the solidified mold resin 135 obtained by cooling the molten mold resin 134 is shaped by cutting, polishing, or the like.

Shaping the solidified mold resin 135 by cutting, polishing, or the like is performed such that the mold resin 132, which is the shaped mold resin, forms a sloped surface 136 that is inclined from top to bottom. The shaping of the solidified mold resin 135 may be performed such that multiple electronic components 131 having predetermined thicknesses are accommodated inside the cavity 102.

After shaping the solidified mold resin 135 by cutting, polishing, or the like, the electronic component assembly 103 with the mold resin 132 formed therein can be manufactured by peeling the carrier 106 from the solidified mold resin 132.

From another point of view, the electronic component assembly 103 may be manufactured, for example, by adopting the following manufacturing process (II). Similar to the above, as illustrated in FIG. 2E, a carrier 106 is prepared for forming the electronic component assembly 103 composed of the multiple electronic components 131 and the mold resin 132. Next, as illustrated in FIG. 2F, the multiple electronic components 131 are placed on an upper surface of the carrier 106.

Next, as illustrated in FIG. 2G(b), a mold resin molding die 107 is prepared for forming a sloped surface 136 that is inclined from top to bottom in the mold resin 132. The mold resin molding die 107 is placed on the carrier 106 so as to surround the electronic components 131. The mold resin molding die 107 has a sloped surface for forming the sloped surface 136 that is inclined from top to bottom in the mold resin 132 constituting the electronic component assembly 103.

Next, as illustrated in FIG. 2H(b), a molten mold resin 134 is poured from above the electronic components 131 into a mold cavity 108 formed by the adhesive tape 105 and the mold resin molding die 107. Then, by cooling the molten mold resin 134 poured into the mold resin molding die 107, the mold resin 132 having the sloped surface 136 that is inclined from top to bottom can be formed.

Next, as illustrated in FIG. 2I, the mold resin molding die 107 is removed from the formed mold resin 132. After that, the carrier 106 is peeled off from the mold resin 132 and multiple electronic components 131 that constitute the electronic component assembly 103. In this way, by peeling off the carrier 106 from the electronic component assembly 103, the electronic component assembly 103 can be manufactured.

In this way, in a method for manufacturing an electronic component built-in substrate according to an embodiment of the present invention, the electronic component assembly 103 can be obtained, for example, through the manufacturing process (I) or the manufacturing process (II), where the mold resin 132 constituting the electronic component assembly 103 has a sloped surface that is inclined from top to bottom.

Next, as illustrated in FIG. 2J, after placing a resin filler 104 on the core substrate 101, the resin filler 104 is heated and pressurized. Further, as illustrated in FIG. 2K, by heating and pressurizing the resin filler 104, the molten resin filler 104 is filled into the cavity 102 and the surface of the core substrate 101. A cavity interior gap 141 formed by the cavity 102 accommodating the electronic component assembly 103, which is composed of the multiple electronic components 131 and the mold resin 132, is eliminated by the filling of the molten resin filler 104 into the cavity 102.

Finally, as illustrated in FIG. 2K, the molten resin filler 104 is cooled and cured. After that, the electronic component built-in substrate 100 can be obtained by peeling off and removing the adhesive tape 105 from the lower surface of the core base material 101, the lower surface of the solidified resin filler 104, and the lower surface of the electronic component assembly 103.

When necessary, a build-up layer can be formed on the manufactured electronic component built-in substrate 100, using the electronic component built-in substrate 100 as a core substrate. For the processing and materials, those known may be used.

In this way, according to a method for manufacturing an electronic component built-in substrate according to an embodiment of the present invention, an electronic component built-in substrate in which multiple electronic components are positioned with high precision can be manufactured by merely forming an extremely simple cavity, without the need of forming protrusions to separate the electronic components within a space for accommodating the electronic components in the cavity of the core substrate.

Further, according to a method for manufacturing an electronic component built-in substrate according to an embodiment of the present invention, even when accommodating multiple electronic components of different sizes in a cavity, an electronic component built-in substrate with a small size can be manufactured without the need of taking into consideration size constraints that require the cavity to be formed in consideration of the size of each electronic component.

Furthermore, according to a method for manufacturing an electronic component built-in substrate according to an embodiment of the present invention, since the sloped surface of the electronic component assembly is inclined from top to bottom, even when a gap formed between the cavity of the core substrate and the electronic components is narrow, the resin filler can be sufficiently filled into the gap.

In a case where multiple electronic components, such as chip capacitors, are accommodated in a single opening in a printed wiring board, when positioning accuracy of the electronic components in the opening is low, it may be possible that connections to the electronic components by via conductors cannot be established. Therefore, a printed wiring board in which electronic components have low positioning accuracy in an opening has reduced connection reliability. From this point of view, a printed wiring board with improved connection reliability by enhancing positioning accuracy of electronic components in an opening has been proposed (Japanese Patent Application Laid-Open Publication No. 2015-220283).

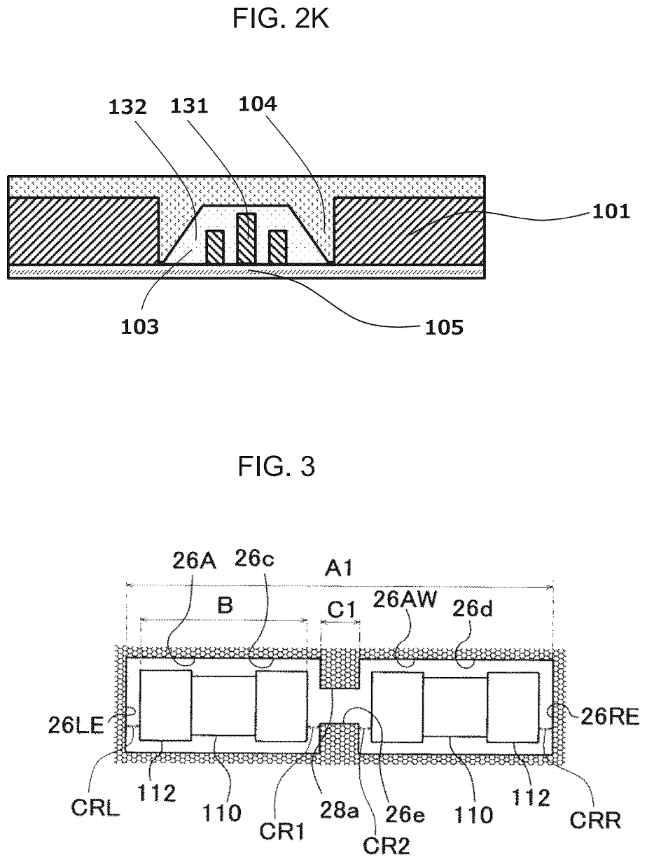

FIG. 3 is a plan view illustrating an example of such a printed wiring board. As illustrated in FIG. 3, a first cavity (26A) of a core substrate in the printed wiring board includes rectangular space part (26c) and space part (26d) for accommodating electronic components, and rectangular first protrusions (28a) for separating the electronic components in the space parts. The first protrusions (28a) protrude from sidewalls (26AW) of the first cavity in directions parallel to first and second surfaces of the core substrate and are formed such that a pair of first protrusions (28a) oppose each other. Between a first protrusion (28a) and an opposing first protrusion (28a), a communication part (26e) connecting the space part (26c) and the space part (26d) is formed.

In the first cavity (26A), the space parts (26c, 26d) for accommodating N electronic components in one direction and N−1 protrusions (28a) for separating the electronic components are formed. In the first cavity (26A), a width (A1) of the cavity in one direction, a width (B) of each electronic component, and a width (C1) at the front end of each protrusion are set to satisfy a predetermined relational expression. In the core substrate of the printed wiring board, two electronic components are accommodated in the first cavity (26A). Therefore, compared to a case where two cavities each accommodating one electronic component are positioned side by side, wiring dead space is reduced and wiring routing is facilitated.

However, in the technology described in Japanese Patent Application Laid-Open Publication No. 2015-220283, rectangular space parts (26c, 26d) for accommodating electronic components in the first cavity (26A) of the core substrate and rectangular first protrusions (28a) for separating the electronic components in the space parts are formed. Therefore, in the technology described in Japanese Patent Application Laid-Open Publication No. 2015-220283, the manufacturing process for forming the first cavity (26A) for accommodating multiple electronic components becomes complicated. Further, the technology described in Japanese Patent Application Laid-Open Publication No. 2015-220283 has a size constraint in that, when accommodating multiple electronic components of different sizes in the first cavity (26A), the first cavity (26A) is formed in consideration of the sizes of the electronic components.

Furthermore, the technology described in Japanese Patent Application Laid-Open Publication No. 2015-220283 has the problem that, when a gap formed between the first cavity (26A) of the core substrate and the electronic components is narrow, a resin filler cannot be sufficiently filled into the gap.

A method for manufacturing an electronic component built-in substrate according to an embodiment of the present invention incorporates multiple electronic components inside a cavity of a core substrate via a resin filler and includes preparing the core substrate; forming the cavity in the core substrate for accommodating an electronic component assembly composed of the multiple electronic components and a mold resin that covers an entirety of the electronic components; placing an adhesive tape on a lower surface of the core substrate; temporarily fixing the electronic component assembly on the adhesive tape in the cavity; filling the cavity in which the electronic component assembly is temporarily fixed with the resin filler and then curing the resin filler; and removing the adhesive tape. The mold resin has a sloped surface that is inclined from top to bottom.

Further, an electronic component built-in substrate with multiple electronic components built-in according to an embodiment of the present invention includes a core substrate; a cavity formed in the core substrate; an electronic component assembly accommodated in the cavity; and a resin filler that covers the core substrate and the electronic component assembly. The electronic component assembly is composed of the electronic components and a mold resin that covers the entirety of the electronic components. The mold resin has a sloped surface that is inclined from top to bottom.

Obviously, numerous modifications and variations of the present invention are possible in light of the above teachings. It is therefore to be understood that within the scope of the appended claims, the invention may be practiced otherwise than as specifically described herein.

1. A method for manufacturing an electronic component built-in substrate, comprising:
preparing a core substrate;
forming a cavity in the core substrate such that the cavity is configured to accommodate an electronic component assembly;
placing an adhesive tape on a surface of the core substrate such that the adhesive tape covers the cavity formed in the core substrate;
temporarily fixing the electronic component assembly on a portion of the adhesive tape exposed in the cavity formed in the core substrate;
filling the cavity in which the electronic component assembly is temporarily fixed with a resin filler such that the resin filler covers the electronic component assembly;
curing the resin filler filling the cavity in which the electronic component assembly is temporarily fixed; and
removing the adhesive tape from the surface of the core substrate such that an electronic component built-in substrate having the electronic component assembly incorporated inside the cavity of the core substrate via the resin filler is formed,
wherein the electronic component assembly comprises a plurality of electronic components and a mold resin covering an entirety of the electronic components and having a sloped surface such that the sloped surface of the mold resin is inclined from a top of the electronic component assembly to a bottom of the electronic component assembly.

2. The method for manufacturing an electronic component built-in substrate according to claim 1, wherein the electronic component assembly is formed such that the electronic components have different heights.

3. The method for manufacturing an electronic component built-in substrate according to claim 1, wherein the core substrate is a copper-clad laminate.

4. The method for manufacturing an electronic component built-in substrate according to claim 1, further comprising:
forming the electronic component assembly comprising the plurality of electronic components and the mold resin covering the entirety of the electronic components such that the sloped surface of the mold resin is inclined from the top of the electronic component assembly to the bottom of the electronic component assembly.

5. The method for manufacturing an electronic component built-in substrate according to claim 2, wherein the core substrate is a copper-clad laminate.

6. The method for manufacturing an electronic component built-in substrate according to claim 2, further comprising:
forming the electronic component assembly comprising the plurality of electronic components and the mold resin covering the entirety of the electronic components such that the sloped surface of the mold resin is inclined from the top of the electronic component assembly to the bottom of the electronic component assembly.

7. The method for manufacturing an electronic component built-in substrate according to claim 3, further comprising:
forming the electronic component assembly comprising the plurality of electronic components and the mold resin covering the entirety of the electronic components such that the sloped surface of the mold resin is inclined from the top of the electronic component assembly to the bottom of the electronic component assembly.

8. The method for manufacturing an electronic component built-in substrate according to claim 5, further comprising:
forming the electronic component assembly comprising the plurality of electronic components and the mold resin covering the entirety of the electronic components such that the sloped surface of the mold resin is inclined from the top of the electronic component assembly to the bottom of the electronic component assembly.

9. The method for manufacturing an electronic component built-in substrate according to claim 4, wherein the forming the electronic component assembly includes shaping the mold resin of the electronic component assembly such that the sloped surface inclined from the top of the electronic component assembly to the bottom of the electronic component assembly is formed.

10. The method for manufacturing an electronic component built-in substrate according to claim 4, wherein the forming the electronic component assembly includes cutting the mold resin of the electronic component assembly such that the sloped surface inclined from the top of the electronic component assembly to the bottom of the electronic component assembly is formed.

11. The method for manufacturing an electronic component built-in substrate according to claim 4, wherein the forming the electronic component assembly includes polishing the mold resin of the electronic component assembly such that the sloped surface inclined from the top of the electronic component assembly to the bottom of the electronic component assembly is formed.

12. The method for manufacturing an electronic component built-in substrate according to claim 4, wherein the forming the electronic component assembly includes placing the electronic components on a surface of a carrier, placing a mold resin molding die configured to form the sloped surface of the mold resin on the carrier such that the electronic components are surrounded, pouring a molten mold resin into a mold cavity of the mold resin molding die, and cooling the molten mold resin poured into the mold resin molding die such that the mold resin having the sloped surface is formed.

13. The method for manufacturing an electronic component built-in substrate according to claim 6, wherein the forming the electronic component assembly includes shaping the mold resin of the electronic component assembly such that the sloped surface inclined from the top of the electronic component assembly to the bottom of the electronic component assembly is formed.

14. The method for manufacturing an electronic component built-in substrate according to claim 6, wherein the forming the electronic component assembly includes cutting the mold resin of the electronic component assembly such that the sloped surface inclined from the top of the electronic component assembly to the bottom of the electronic component assembly is formed.

15. The method for manufacturing an electronic component built-in substrate according to claim 6, wherein the forming the electronic component assembly includes polishing the mold resin of the electronic component assembly such that the sloped surface inclined from the top of the electronic component assembly to the bottom of the electronic component assembly is formed.

16. The method for manufacturing an electronic component built-in substrate according to claim 6, wherein the forming the electronic component assembly includes placing the electronic components on a surface of a carrier, placing a mold resin molding die configured to form the sloped surface of the mold resin on the carrier such that the electronic components are surrounded, pouring a molten mold resin into a mold cavity of the mold resin molding die, and cooling the molten mold resin poured into the mold resin molding die such that the mold resin having the sloped surface is formed.

17. An electronic component built-in substrate, comprising:
a core substrate having a cavity;
an electronic component assembly accommodated in the cavity and comprising a plurality of electronic components; and
a resin filler filling the cavity of the core substrate such that the resin filler is covering the core substrate and the electronic component assembly,
wherein the electronic component assembly comprises a mold resin covering an entirety of the electronic components and having a sloped surface such that the sloped surface of the mold resin is inclined from a top of the electronic component assembly to a bottom of the electronic component assembly.

18. The electronic component built-in substrate according to claim 17, wherein the electronic component assembly is formed such that the electronic components have different heights.

19. The electronic component built-in substrate according to claim 17, wherein the core substrate is a copper-clad laminate.

20. The electronic component built-in substrate according to claim 18, wherein the core substrate is a copper-clad laminate.
